(19) United States
(12) Patent Application Publication
(10) Pub. No.: US 2025/0271074 A1
(43) Pub. Date: Aug. 28, 2025

(54) BUTTERFLY VALVE CONTROL METHOD AND DEVICE

(71) Applicant: MECARO CO.,LTD, Pyeongtaek-si (KR)

(72) Inventors: Sungyoon JUNG, Gunpo-si (KR); Taehyeok KIM, Cheonan-si (KR); Junyeung KIM, Gunpo-si (KR)

(21) Appl. No.: 18/704,992

(22) PCT Filed: Nov. 13, 2023
(86) PCT No.: PCT/KR2023/018147

§ 371 Date: Apr. 26, 2024

(30) Foreign Application Priority Data
Jul. 5, 2023 (KR) 10-2023-0087022
Sep. 5, 2023 (KR) 10-2023-0117592

(51) Int. Cl. F16K 31/04; F16K 1/22; F16K 27/02; F16K 31/53; F16K 37/00; F16K 47/04

(52) U.S. Cl. CPC F16K 31/042; F16K 1/22; F16K 27/0218; F16K 31/535; F16K 37/0083; F16K 37/0091; F16K 47/04

(57) ABSTRACT

A butterfly valve control device includes: a butterfly valve placed on a conduit line through which fluid communicates with an inside of a chamber and including a valve body in which a valve passage communicating with the conduit line is defined through an inner wall and including a plate that is connected to the valve body through a shaft and adjusts a flow rate of fluid passing through the valve passage according to rotation of the shaft in an axial direction; a valve drive unit that provides a rotational force to rotate the shaft; a valve control unit that provides a control signal to the valve drive unit to control a pressure in the chamber according to rotation of the plate in an axial direction; a first sensing unit that senses the pressure in the chamber and generates pressure information; and a memory that stores high-speed rotation information

### CROSS-REFERENCE TO RELATED APPLICATIONS

The present disclosure is a national phase application under 35 U.S.C. § 371 of International Application No. PCT/KR2023/018147 filed Nov. 13, 2023, which claims the benefit of and priority to Korean Patent Application No. 10-2023-0087022 filed Jul. 5, 2023, and Korean Patent Application No. 10-2023-0117592 filed Sep. 5, 2023, the contents of which being incorporated by reference in their entireties herein.

### TECHNICAL FIELD

The present disclosure relates to a butterfly valve control method and device, and particularly, to method and device for controlling a butterfly valve that is applied to a chamber system and automatically adjusts the pressure in a chamber.

### BACKGROUND

The description given in this section simply provides background information on the present embodiment and does not constitute the conventional art.

A butterfly valve may provide a function of adjusting the flow of fluid guided through a valve passage formed in a valve body according to the degree of rotation of a plate and substantially closing the flow path. That is, the supply or discharge of fluid flowing into a specific environment through a butterfly valve may be controlled, and the creation of a closed environment may be supported. Butterfly valves are mainly applied to process chambers that manufacture highly sensitive semiconductor elements and provide a function of maintaining the pressure in the process chambers according to process conditions.

Conventionally, pressure control in a process chamber through a butterfly valve is performed based on feedback information (pressure value) provided from the chamber. A control device generates an output signal such that a currently measured pressure value follows a target pressure value, and controls the rotation of a butterfly valve according to an output signal. As the above-described control process is repeatedly performed, the final target pressure may be formed in a chamber.

The conventional control method is performed based on feedback information on a chamber, and time loss inevitably occurs as the feedback information is acquired and analyzed. That is, a time delay occurs in the process of quickly achieving the process conditions of a chamber, and problems may occur in which the quality and reliability of a final product are reduced during a manufacturing process of semiconductor elements that require fineness and high sensitivity.

Accordingly, there is a need for a butterfly valve control method and device that may support a chamber process to be performed more quickly and reliably by providing a more rapid and reliable control method.

### BRIEF SUMMARY

An object of the present disclosure is to provide a control method and control device that may more quickly and reliably control a butterfly valve which is applied to a chamber system and automatically adjusts the pressure in a chamber.

Objects of the present disclosure are not limited to the objects described above, and other objects and advantages of the present disclosure that are not described may be understood by the following descriptions and will be more clearly understood by examples of the present disclosure. Also, it will be readily apparent that the objects and advantages of the present disclosure may be realized by means and combinations thereof indicated in the patent claims.

According to some aspects of the disclosure, a butterfly valve control device comprises: a butterfly valve placed on a conduit line through which fluid communicates with an inside of a chamber and including a valve body in which a valve passage communicating with the conduit line is defined through an inner wall and including a plate that is connected to the valve body through a shaft and adjusts a flow rate of fluid passing through the valve passage according to rotation of the shaft in an axial direction, a valve drive unit that provides a rotational force to rotate the shaft; a valve control unit that provides a control signal to the valve drive unit to control a pressure in the chamber according to rotation of the plate in an axial direction, a first sensing unit that senses the pressure in the chamber and generates pressure information, and a memory that stores high-speed rotation information for each pressure in the chamber, wherein the valve control unit controls an internal pressure of the chamber through at least one of a first control mode for generating a first control signal based on the high-speed rotation information for each pressure and controlling a rotation angle of the plate according to the first control signal, and a second control mode for generating a second control signal such that the pressure information follows a target pressure and controlling the rotation angle of the plate according to the second control signal. According to some aspects, the plate controls an operation between a closed state in which the valve passage is closed as the shaft does not rotate and an open state in which the valve passage is open as the shaft rotates, the plate is placed such that a gap of a predetermined width with the inner wall is formed in the closed state, and the butterfly valve is in an unsealed state in the closed state.

According to some aspects, the valve control unit controls the rotation angle of the plate by first applying a first control mode in response to a control start signal, and in the first control mode, the valve control unit generates the first control signal by recalling the rotation angle of the plate corresponding to the set target pressure from the high-speed rotation information for each pressure.

According to some aspects, the valve control unit determines whether to switch from the first control mode to the second control mode based on an amount of change in the target pressure and the pressure information.

According to some aspects, the valve control unit determines whether the target pressure is the same as the pressure information, determines the amount of change in the pressure information when the target pressure is not the same as the pressure information, maintains the first control mode when the amount of change in the pressure information exceeds a preset reference value, and switches to the second control mode when the amount of change in the pressure information is less than the preset reference value.

According to some aspects, the valve control unit configures actual measurement information by mapping the pressure information to a current rotation angle of the plate, and updates the high-speed rotation information for each pressure based on the actual measurement information.

According to some aspects, the memory is a non-volatile memory.

According to some aspects, the valve drive unit includes: a motor that generates a rotational force for rotating the shaft according to one of the first control signal and the second control signal; a coupler connected to the shaft and transferring the rotational force provided by the motor; a gear box provided between the coupler and the motor to adjust a reduction ratio of the rotational force; and an encoder that generates first rotation angle information according to driving of the motor, and the rotation angle information is generated based on the first rotation angle information.

According to some aspects, further comprising a second sensing unit that generates a plate image by imaging a plate, wherein the second sensing unit is configured to analyze the plate image and determine a degree of accumulation of by-products in the plate.

According to some aspects of the disclosure, a method of controlling a butterfly valve placed on a conduit line through which fluid communicates with an inside of a chamber and including a valve body in which a valve passage communicating with the conduit line is defined through an inner wall and including a plate that is connected to the valve body through a shaft and adjusts a flow rate of fluid passing through the valve passage according to rotation of the shaft in an axial direction, the method comprises: a step of recalling a rotation angle of the plate corresponding to a set target pressure from high-speed rotation information for each pressure stored in a memory, and performing a first control mode for rotating the plate by controlling the shaft according to the recalled rotation angle of the plate, a step of determining whether to maintain the first control mode by comparing a pressure of a chamber with the set target pressure, and switching to the second control mode when a difference between the set target pressure and the pressure of the chamber is less than a preset reference value, a step of calculating a control input for adjusting the rotation angle of the plate such that the pressure of the chamber follows the target pressure, and performing the second control mode for rotating the plate by controlling the shaft based on the control input, and a step of configuring actual measurement information by mapping the pressure of the chamber to the rotation angle of the plate, and updating the high-speed rotation information for each pressure based on the actual measurement information.

Aspects of the disclosure are not limited to those mentioned above and other objects and advantages of the disclosure that have not been mentioned can be understood by the following description and will be more clearly understood according to embodiments of the disclosure. In addition, it will be readily understood that the objects and advantages of the disclosure can be realized by the means and combinations thereof set forth in the claims.

A butterfly valve control method and device according to some embodiments of the present disclosure may perform a first control mode for adjusting in advance an angle of a plate through high-speed rotation information for each pressure, thereby shortening a control time and control cycle for a chamber to reach a target pressure, and supporting an increase in quality and reliability of a process performed in the chamber.

Also, a butterfly valve control method and device according to some embodiments of the present disclosure may support more precise control by updating high-speed rotation information for each pressure according to a state change occurring as a process is performed and may store the high-speed rotation information for each pressure in a non-volatile memory to support the use of updated high-speed rotation information for each pressure not only in a current process but also in a future process.

In addition to the above description, specific effects of the present disclosure are described below while describing specific details for implementing the disclosure.

### BRIEF DESCRIPTION OF THE DRAWINGS

FIG. 1 is a block diagram illustrating a configuration of a butterfly valve control device according to some embodiments of the present disclosure.

FIG. 2 is a perspective view of a butterfly valve according to some embodiments of the present disclosure.

FIGS. 3A and 3B are example views illustrating a relationship between a plate and the inside of a valve body, according to some embodiments of the present disclosure.

FIG. 4 is an example diagram illustrating a configuration and function of a valve control unit according to some embodiments of the present disclosure.

FIG. 5 is a flowchart illustrating a butterfly valve control method according to some embodiments of the present disclosure.

FIG. 6 is an example diagram illustrating a first control mode according to some embodiments of the present disclosure.

FIG. 7 is an example diagram illustrating a process of switching control modes, according to some embodiments of the present disclosure.

FIG. 8 is an example diagram illustrating a second control mode according to some embodiments of the present disclosure.

FIG. 9 is an example diagram illustrating a process of updating high-speed rotation information for each pressure, according to some embodiments of the present disclosure.

### DETAILED DESCRIPTION

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

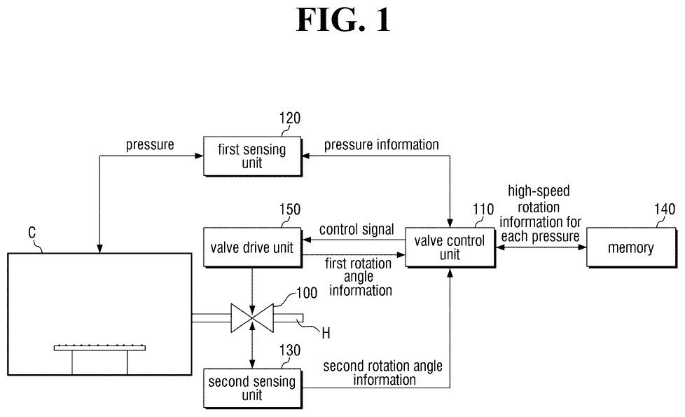

Hereinafter, a butterfly valve control method and device according to some embodiments of the present disclosure will be described with reference to FIGS. 1 to 9.

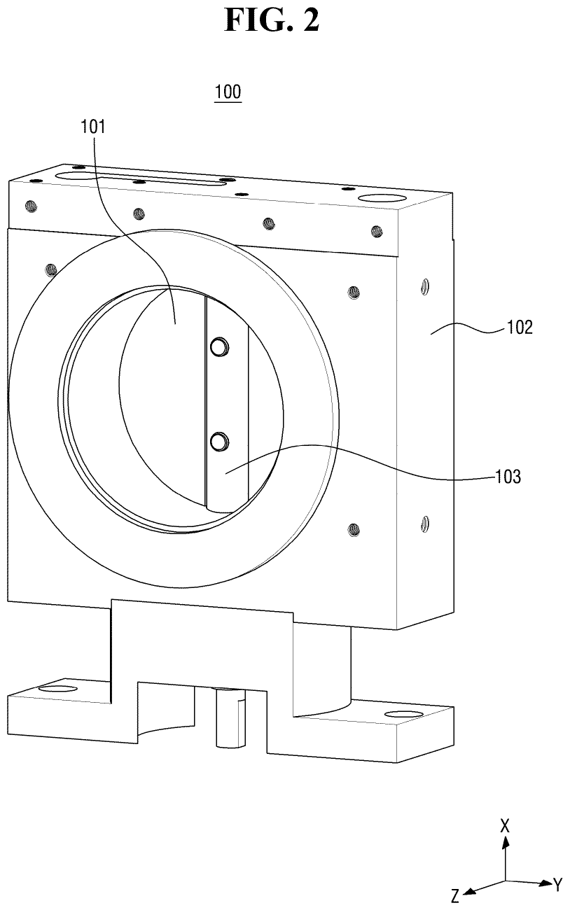

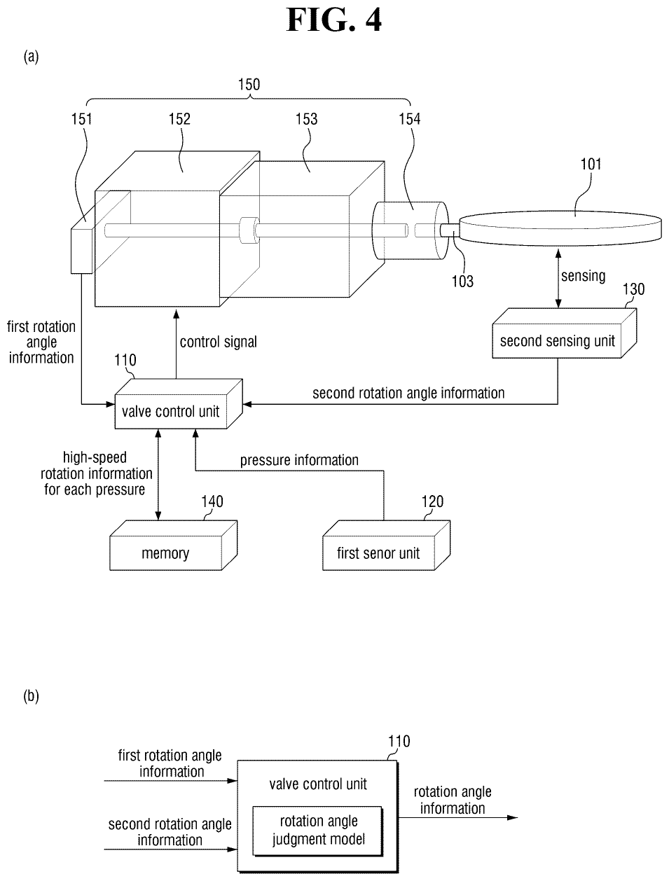

FIG. 1 is a block diagram illustrating a configuration of a butterfly valve control device according to some embodiments of the present disclosure. FIG. 2 is a perspective view of a butterfly valve according to some embodiments of the present disclosure. 3A and 3B are example views illustrating a relationship between a plate and the inside of a valve body, according to some embodiments of the present disclosure. FIG. 4 is an example diagram illustrating a configuration and function of a valve control unit according to some embodiments of the present disclosure.

Referring to FIG. 1, a butterfly valve control device 10 includes a butterfly valve 100, a valve control unit 110, a first sensing unit 120, a second sensing unit 130, a memory 140, and a valve drive unit 150.

The butterfly valve 100 may be located on a conduit line H through which fluid communicates with the inside of a chamber C. The chamber C may be a closed space where physical and chemical reactions are performed, such as in a semiconductor process. For example, the chamber C may be a space where a chemical vapor deposition (CVD) process is performed to form a thin film on a substrate, but embodiments of the present disclosure are not limited thereto. A state in which the chamber C and the conduit line H communicate with an external space may change depending on operation states of the butterfly valve 100, and accordingly, a change in pressure in the chamber C may occur.

Referring to FIG. 2, the butterfly valve 100 may include at least a plate 101, a valve body 102, and a shaft 103.

The plate 101 may be a thin plate with a predetermined thickness. The valve body 102 constitutes the entire appearance of a valve, and a valve passage G communicating with the conduit line H may be defined through an inner wall. The valve passage G may be an open region opened to communicate with the conduit line H. The plate 101 may be disposed to correspond to the valve passage G and configured to open and close the valve passage G. The plate 101 may have a shape corresponding to the valve passage G. For example, when the valve passage G is defined as a circular shape, the plate 101 may also be configured as a circular shape. Here, as illustrated in FIG. 2, a direction in which fluid communicates on the conduit line H may be a Z-axis direction, and when the plate 101 is placed to correspond to an X-Y plane, the valve passage G may be substantially closed.

The shaft 103 may be configured to partially pass through the valve body 102, and an end of the shaft 103 may be rotatably connected to the valve body 102. In a state of being connected to the valve body 102, the shaft 103 may be configured to rotate clockwise or counterclockwise. The shaft 103 may be configured to extend in an X-axis direction and may be rotated in an axial direction. The shaft 103 may be connected to the plate 101 in a state where the shaft 103 extends to pass through the center of the plate 101. The plate 101 rotates according to the rotation of the shaft 103, and an area of the valve passage G changes according to the rotation of the shaft 103. The plate 101 may adjust a flow rate of fluid passing through the valve passage G according to rotation in the axial direction of the shaft 103.

The plate 101 controls an operation between a closed state in which the valve passage G is closed as the shaft 103 does not rotate and an open state in which the valve passage G is open as the shaft 103 rotates.

In a state in which the shaft 103 does not rotate, the plate 101 may be placed to correspond to the X-Y plane and substantially close the valve passage G.

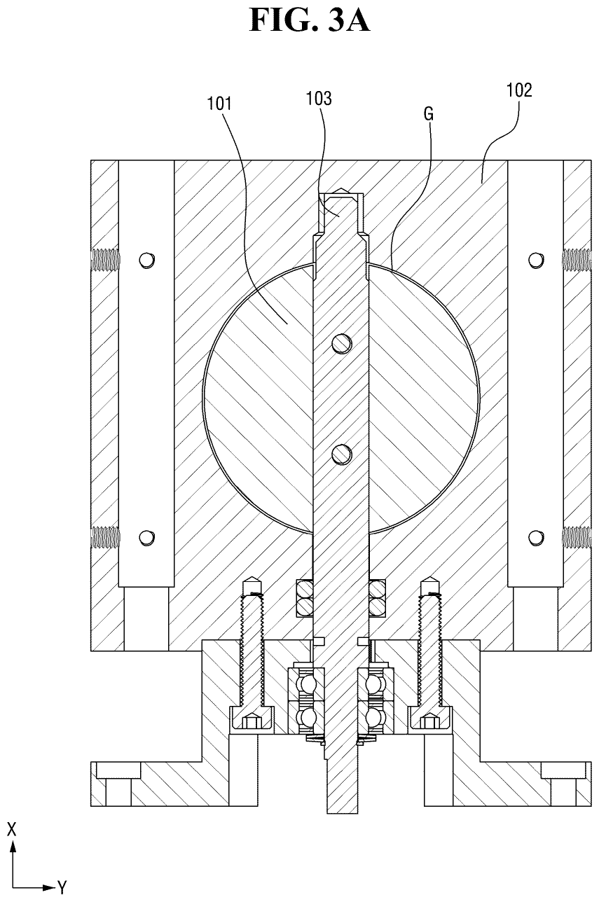

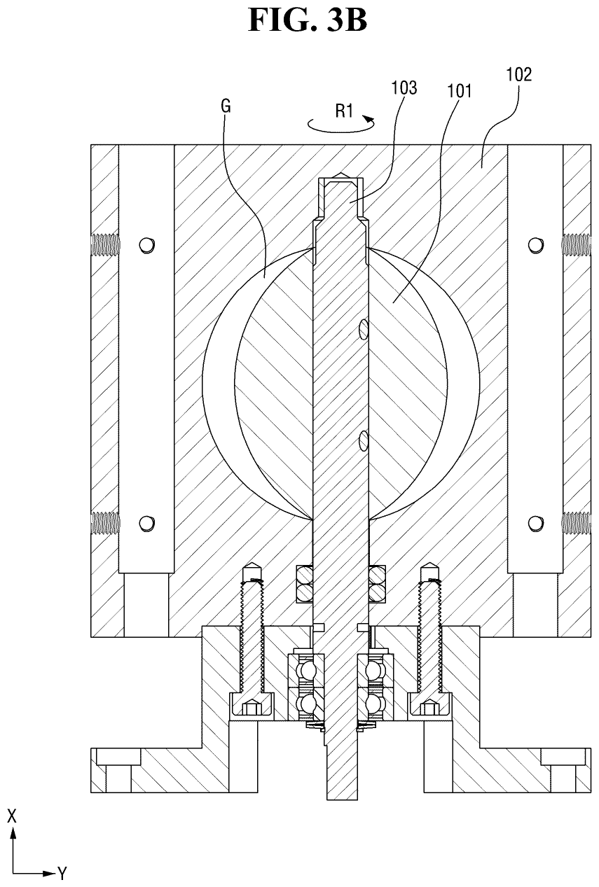

A state illustrated in FIG. 3A may be defined as a closed state. As exemplarily illustrated in FIG. 3B, when the shaft 103 partially rotates in a counterclockwise direction R1, the plate 101 may also rotate together. An open state may be defined as a state in which an area of the valve passage G increases compared to the closed state as the plate 101 rotates. As the closed state is changed to the open state, an area of the valve passage G is expanded, and a flow rate of fluid flowing into or out of the chamber C changes, and accordingly, the pressure of the chamber C changes.

Here, the plate 101 may be placed such that a gap of a predetermined width with an inner wall is formed in the closed state. Referring to FIG. 3A, it can be seen that a predetermined gap is formed between the plate 101 and the inner wall. The butterfly valve 100 may be in an unsealed state in the closed state, and is not in an unsealed state in which the movement of fluid is completely blocked. The main purpose of the butterfly valve 100 may be to maintain the pressure in the chamber C at a certain level by adjusting a flow rate of fluid flowing into or out of the chamber C, and this function may be performed in an unsealed state.

The valve control unit 110 may control the plate 101 of the butterfly valve 100 to rotate based on the X-axis direction, thereby controlling the pressure in the chamber C. The valve control unit 110 may rotate the shaft 103, on which the plate 101 is fixed, clockwise or counterclockwise based on an axial direction and may change an area of a valve passage covered by the plate 101. The pressure of the chamber C changes in response to a change in area of the valve passage G due to an axial direction rotation of the plate 101.

Control of the butterfly valve 100 performed by the valve control unit 110 may be performed based on a state of the chamber C, a state of the butterfly valve 100, and high-speed rotation information for each pressure stored in the memory 140.

The memory 140 may include the high-speed rotation information for each pressure. Here, the high-speed rotation information for each pressure may be information stored by presetting a rotation angle of the plate 101 for each target pressure. That is, the high-speed rotation information for each pressure may be information that is pre-mapped and stored such that the pressure corresponds to the rotation angle of the plate 101. In some embodiments, the high-speed rotation information for each pressure may be referred to as a pre-rotation angle for each pressure. The valve control unit 110 may generate a control signal suitable for the current state of the chamber C based on at least one piece of the prior information stored in the memory 140 and the actually measured information, and may provide the control signal to the valve drive unit 150 to control such that the plate 101 is maintained to rotate at an appropriate rotation angle. That is, the valve control unit 110 may generate a first control signal based on the high-speed rotation information for each pressure, generate a second control signal such that pressure information follows a target pressure, and control the pressure in the chamber C through at least one of the first control mode for controlling a rotation angle of the plate according to a first control signal and a second control mode for controlling the rotation angle of the plate according to the second control signal.

The first sensing unit 120 may sense a state of the chamber C and provide information on the chamber C to the valve control unit 110. Specifically, the first sensing unit 110 may generate pressure information by sensing the pressure in the chamber C and provide the pressure information to the valve control unit 110.

Rotation angle information of the butterfly valve 100 may be provided from the valve drive unit 150. The valve drive unit 150 may sense the degree of rotation of the shaft 103 and generate first rotation angle information based thereon. The valve drive unit 150 may provide the generated first rotation angle information to the valve control unit 110.

Specifically, referring to FIG. 4(a), the valve drive unit 150 includes an encoder 151, a motor 152, a gear box 153, and a coupler 154.

The motor 152 generates a rotational force for rotating the shaft 103 based on a control signal provided from the valve control unit 110. The motor 152 may rotate the shaft 103 clockwise or counterclockwise according to either the first control signal according to the first control mode or the second control signal according to the second control mode. The shaft 103 and the motor 152 may be connected to each other through the coupler 154, and the gear box 153 may be placed between the coupler 154 and the motor 152. The gear box 153 may be configured to adjust a reduction ratio of the rotational force generated by the motor 152. The encoder 151 may generate first rotation angle information according to driving of the motor. That is, the encoder 151 may sense a drive state of the motor and determine a rotation state and the degree of rotation of the shaft 103, and based on this, may generate first rotation angle information indicating the degree of rotation of the plate 101.

In an embodiment, the valve control unit 110 may determine a rotation degree and rotation angle information of the plate 101 based on the first rotation angle information. However, embodiments of the present disclosure are not limited thereto. In some embodiments, the valve control unit 110 may be further configured to determine the rotation degree and rotation angle information of the plate 101 by further considering the second rotation angle information generated based on an actual rotation state of the plate 101.

The second sensing unit 130 may further sense a state of the butterfly valve 100. The second sensing unit 130 may sense the second rotation angle information by determining the degree of rotation of the plate 101 of the butterfly valve 100. The second sensing unit 130 may be configured as a vision sensor and may generate a plate image by imaging a current state of the plate 101. The second sensing unit 130 may include a first image analysis model that generates the second rotation angle information by analyzing the plate image.

The first image analysis model may be a deep learning-based artificial intelligence analysis model and generate rotation angle information obtained by determining the degree of rotation of the plate 101 by analyzing the size of a gap between an inner wall and the plate 101 in an input image.

In some embodiments, the second sensing unit 130 may include a second image analysis model that further analyzes the generated plate image and determines the amount of by-products accumulated in the plate 101. While a process of the chamber C is performed, by-products or so on of the process may be accumulated, and the accumulated by-products may become a factor that interferes with precise control of the plate 101.

The second sensing unit 130 may generate by-product accumulation information for determining the degree of accumulation of by-products by analyzing the plate image generated through the second image analysis model. The second image analysis model may be a deep learning-based artificial intelligence learning model and may be a pre-trained model to identify by-products in the input image and determine the dose of the identified by-product. When the by-product accumulation information exceeds a preset threshold, the second sensing unit 130 may send an alarm requesting an action on the plate 101 to support a user in taking appropriate action. The second rotation angle information generated by the second sensing unit 130 may be provided to the valve control unit 110.

The valve control unit 110 may receive both the first rotation angle information generated based on the rotation of the motor 152 and the second rotation angle information generated by determining an actual degree of rotation of the plate 101. Here, the first rotation angle information and the second rotation angle information may be sensed at the same angle, but may also be determined to be different angles depending on states of the butterfly valve 100. Therefore, the valve control unit 110 may generate rotation angle information that is basic data for generating a control signal based on the first rotation angle information and the second rotation angle information, and generate a control signal based on the rotation angle information.

Referring to FIG. 4(b), the valve control unit 110 may include a rotation angle analysis model that generates final rotation angle information based on the first rotation angle information and second rotation angle information which are input. The rotation angle analysis model may be a deep learning-based artificial intelligence learning model but is not limited thereto. In some embodiments, the rotation angle analysis model may generate rotation angle information by applying weights to the first rotation angle information and the second rotation angle information and summing the weights. Also, in some embodiments, the rotation angle analysis model may further receive pressure information of the chamber C and time information at which a process is performed and may generate rotation angle information by further considering the pressure information and time information. The rotation angle analysis model may determine a weight applied to calculation according to the pressure information of the chamber C and the time information at which a process is performed, and a final weight may be determined by applying the determined weight to the first rotation angle information and the second rotation angle information. The valve control unit 110 may control the butterfly valve 100 by using the finally determined rotation angle information.

As described above, based on the collected information, the valve control unit 110 may control the butterfly valve 100 through at least one of the first control mode and the second control mode. The valve control unit 110 may control a rotation angle of the plate 101 by first applying the first control mode in response to a control start signal. In the first control mode, the valve control unit 110 may generate a first control signal by recalling a rotation angle of the plate corresponding to the set target pressure from high-speed rotation information for each pressure.

Also, the valve control unit 110 may determine whether to switch from the first control mode to the second control mode based on the amount of change in the target pressure and pressure information. Also, the valve control unit 110 may determine whether the target pressure is the same as the pressure information, and when the target pressure is not the same as the pressure information, the valve control unit 110 may determine the amount of change in the pressure information, and when the amount of change in the pressure information exceeds a preset reference value, the valve control unit 110 may maintain the first control mode, and when the amount of change in the pressure information is less than or equal to the preset reference value, the valve control unit 110 may be switched to the second control mode.

Also, the valve control unit 110 configures actual measurement information by mapping the pressure information to the current rotation angle of the plate and may update the high-speed rotation information for each pressure based on the actual measurement information. Here, the memory 140 may be a non-volatile memory, and after the process of the chamber C is completed, the updated high-speed rotation information for each pressure may be used in a state where a new process is performed.

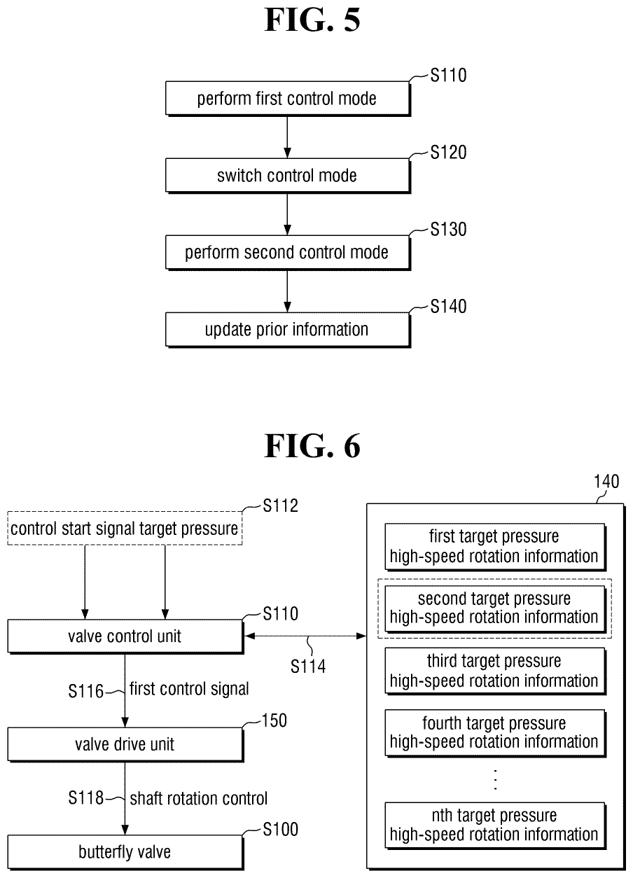

Hereinafter, a butterfly valve control method according to some embodiments of the present disclosure will be described in more detail with reference to FIGS. 5 to 9.

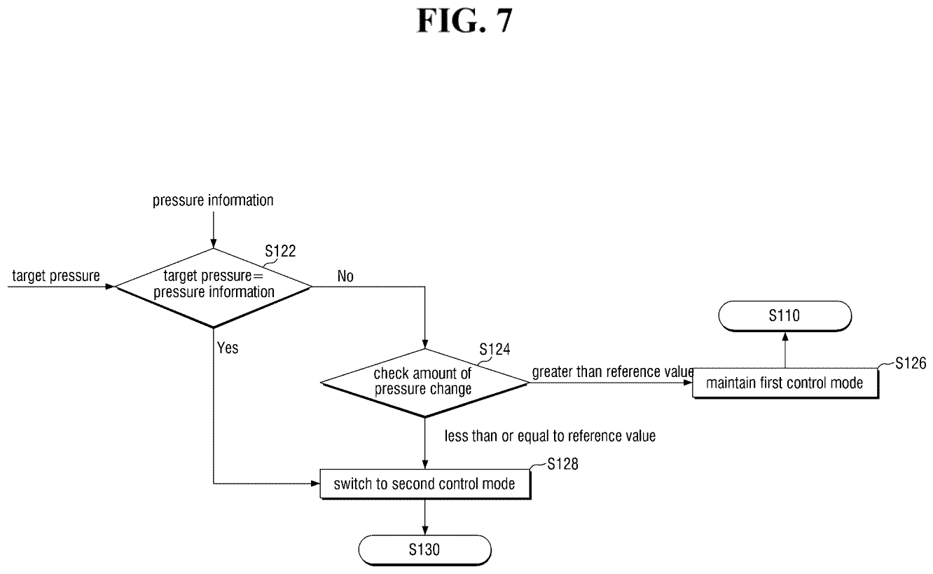

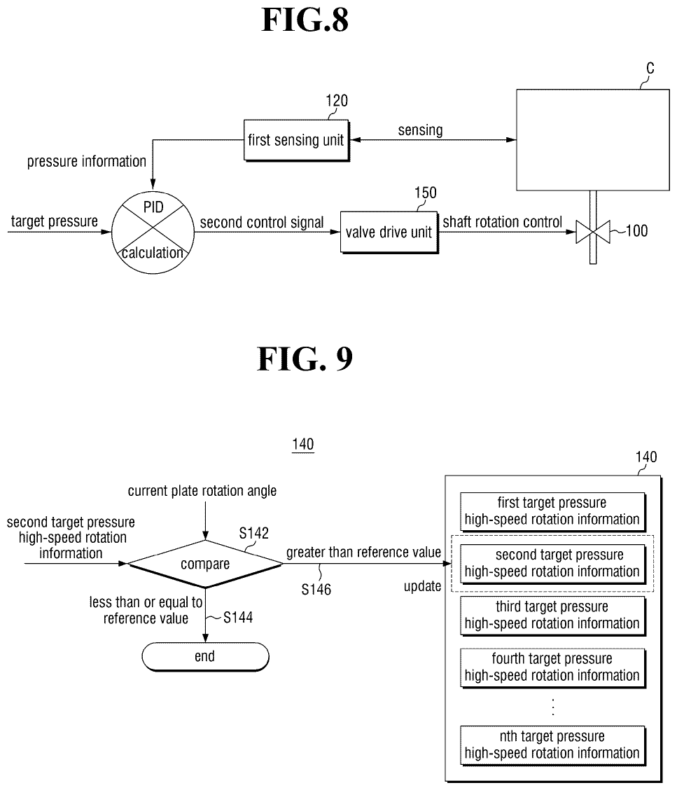

FIG. 5 is a flowchart illustrating a butterfly valve control method according to some embodiments of the present disclosure. FIG. 6 is an example diagram illustrating a first control mode according to some embodiments of the present disclosure. FIG. 7 is an example diagram illustrating a process of switching control modes, according to some embodiments of the present disclosure. FIG. 8 is an example diagram illustrating a second control mode according to some embodiments of the present disclosure. FIG. 9 is an example diagram illustrating a process of updating high-speed rotation information for each pressure, according to some embodiments of the present disclosure.

Referring to FIG. 5, the butterfly valve 100 control method according to some embodiments is a control method performed by a butterfly valve control device 10, specifically, the valve control unit 110, and includes step S110 of performing a first control mode, step S120 of switching a control mode, step S130 of performing a second control mode, and step S140 of updating prior information.

In an embodiment of the present disclosure, a process of generating a first control signal or a second control signal by the valve control unit 110 and controlling an angle of the plate 101 of the butterfly valve 100 in response thereto may be defined as one cycle. The first control mode of step S110 and the second control mode of step S130 may each consist of at least one cycle, and a cycle for forming and maintaining a target pressure in the chamber C is performed repeatedly.

First, the first control mode is performed (S110). Referring to FIG. 6, a control start signal is provided, and the target pressure is set (S112). The control start signal and the target pressure may be generated according to an input from a high-level controller or user to be provided. The valve control unit 110 controls a rotation angle of the butterfly valve 100 by first applying the first control mode in response to the control start signal.

The first control mode corresponds to a control process of setting the rotation angle of the plate 101 at high speed based on the rotation angle corresponding to the target pressure and high-speed rotation information for each pressure and. That is, the rotation of the plate 101 according to the first control mode may be a high-speed rotation performed in a short period of time by using previously stored data and high-speed rotation information for each pressure corresponding to the set value without being based on sensing and measuring a state of the chamber C.

Accordingly, the plate 101 may form a prior angle regardless of the pressure state of the chamber C according to high-speed rotation in the first control mode. Accordingly, the time for controlling an angle of the chamber C to reach a stable state and target pressure may be shortened, and the quality and reliability of a process performed in the chamber C may be increased.

The high-speed rotation information for each pressure may be stored in the memory 140, and as exemplarily illustrated in FIG. 6, a rotation angle of the plate 101 may be recorded in advance for each target pressure. That is, the high-speed rotation information for each pressure may be information that is mapped and stored in advance such that the pressure corresponds to the rotation angle of the plate 101. The memory 140 may store first to nth target pressure high-speed rotation information. Here, n may be a natural number of 2 or more, and the first to nth target pressures may indicate different pressure values. The high-speed rotation information for each pressure may correspond to information prepared in advance and may be updated by reflecting information that changes during the process.

For example, when the target pressure set in step S112 is a second target pressure, the valve control unit 110 may recall the second target pressure high-speed rotation information from the memory 140 (S114) and generate the first control signal for controlling the plate 101 to form a rotation angle corresponding to the second target pressure high-speed rotation information. The first control signal is provided to the valve drive unit 150 (S116). The valve drive unit 150 may rotate the shaft 103 in response to the first control signal (S118). In response to the rotation of the shaft 103, the plate 101 of the butterfly valve 100 is rotated to form a predetermined rotation angle, and accordingly, the pressure of the chamber C is controlled.

Next, the valve control unit 110 switches a control mode (S120).

In step S120, the valve control unit 110 may determine whether to switch the first control mode to the second control mode. When a current state of the chamber C satisfies a preset condition, the valve control unit 110 switches to the second control mode and performs more precise control. Specifically, the valve control unit 110 may determine whether to switch from the first control mode to the second control mode based on a target pressure and the amount of change in pressure information.

Referring to FIG. 7, the valve control unit 110 may compare pressure information obtained by measuring the pressure of the chamber C with the target pressure (S122). Here, when the pressure information and the target pressure are in the same state (Yes), a control goal of the valve control unit 110 may be in a state of being substantially achieved, and switching to the second control mode may be performed to maintain the current state (S128). In step S122, when the pressure information and the target pressure are not the same as each other (No), the valve control unit 110 checks the amount of pressure change in the chamber C (S124). Here, the amount of pressure change may mean a difference between the pressure information of the chamber C measured in the current cycle and the pressure information of the chamber C measured in the previous cycle.

In step S124, when the amount of pressure change is less than the reference value, the chamber C is considered to be in a stable state in which the change in pressure is not large, and switching to the second control mode is performed for precise control (S128). In contrast to this, in step S124, when the amount of pressure change exceeds the reference value, a stable state may not be reached yet, or a rotation angle according to high-speed rotation may not be reached. when the amount of pressure change exceeds the reference value, it may be determined that the valve control unit 110 continuously maintains the first control mode (S126). After switching to the second control mode is determined, the processing proceeds to a step of performing the second control mode (S130).

The second control mode, which is performed in step S130, includes a process of controlling a rotation angle of the plate 101 by generating the second control signal such that the currently measured pressure of the chamber C follows the target pressure.

Exemplarily, the valve control unit 110 may perform a PID operation on the target pressure and pressure information as illustrated in FIG. 8 and generate the second control signal based thereon. The valve control unit 110 may receive a target pressure and pressure information, perform a PID operation including proportionality, integration, and differentiation on the received values, and generate the second control signal. The second control signal may be provided to the valve drive unit 150, and the valve drive unit 150 may rotate the shaft 103 according to the second control signal. In response to the rotation of the shaft 103, the plate 101 of the butterfly valve 100 rotates to form a predetermined rotation angle, and accordingly, the pressure of the chamber C is controlled.

While the second control mode is provided, a control cycle according to the above-described process may be performed at least once, and accordingly, the pressure of the chamber C may be controlled to meet the target pressure and be in a stable state.

Next, in the process of performing the second control mode or after the chamber C enters the stable state, the valve control unit 110 may perform step S140 of updating high-speed rotation information for each pressure by using rotation angle information of the plate 101.

As the process is performed in the chamber C, states of the plate 101 and the butterfly valve 100 may also change, and a change may occur in the degree of rotation in response to a control signal. The valve control unit 110 may update the preset high-speed rotation information by reflecting a change in state. In step S140, the valve control unit 110 may configure actual measurement information by mapping the pressure information and the current rotation angle of a plate and may update the high-speed rotation information for each pressure based on the actual measurement information.

Referring to FIG. 9, the second target pressure high-speed rotation information corresponding to a second target pressure which is a currently set target pressure may be compared with a current plate rotation angle (S142). In step S142, when the result is less than or equal to a reference value, the current second target pressure high-speed rotation information is maintained, and an ending process is performed without performing update (S144). In step S142, when the result exceeds the reference value, a process of updating the current plate rotation angle to the second target pressure high-speed rotation information is performed (S146). Here, the memory 140 may be a non-volatile memory, and after the process in the chamber C is completed, the updated high-speed rotation information for each pressure may be used while a new process is performed.

A butterfly valve control method and device according to some embodiments of the present disclosure may perform a first control mode for adjusting in advance an angle of a plate through high-speed rotation information for each pressure, thereby shortening a control time and control cycle for a chamber to reach a target pressure, and supporting an increase in quality and reliability of a process performed in the chamber.

Also, a butterfly valve control method and device according to some embodiments of the present disclosure may support more precise control by updating high-speed rotation information for each pressure according to a state change occurring as a process is performed and may store the high-speed rotation information for each pressure in a non-volatile memory to support the use of updated high-speed rotation information for each pressure not only in a current process but also in a future process. While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

1. A butterfly valve control device, comprising:
a butterfly valve placed on a conduit line through which fluid communicates with an inside of a chamber and comprising a valve body in which a valve passage communicating with the conduit line is defined through an inner wall and comprising a plate that is connected to the valve body through a shaft and adjusts a flow rate of fluid passing through the valve passage according to rotation of the shaft in an axial direction;
a valve drive unit that provides a rotational force to rotate the shaft;
a valve control unit that provides a control signal to the valve drive unit to control a pressure in the chamber according to rotation of the plate in an axial direction;
a first sensing unit that senses the pressure in the chamber and generates pressure information; and
a memory that stores high-speed rotation information for each pressure in the chamber,
wherein the valve control unit controls an internal pressure of the chamber through at least one of a first control mode for generating a first control signal based on the high-speed rotation information for each pressure and controlling a rotation angle of the plate according to the first control signal, and a second control mode for generating a second control signal such that the pressure information follows a target pressure and controlling the rotation angle of the plate according to the second control signal.

2. The butterfly valve control device of claim 1, wherein;
the plate controls an operation between a closed state in which the valve passage is closed as the shaft does not rotate and an open state in which the valve passage is open as the shaft rotates,
the plate is placed such that a gap of a predetermined width with the inner wall is formed in the closed state, and
the butterfly valve is in an unsealed state in the closed state.

3. The butterfly valve control device of claim 1, wherein;
the valve control unit controls the rotation angle of the plate by first applying a first control mode in response to a control start signal, and
in the first control mode, the valve control unit generates the first control signal by recalling the rotation angle of the plate corresponding to the set target pressure from the high-speed rotation information for each pressure.

4. The butterfly valve control device of claim 3, wherein the valve control unit determines whether to switch from the first control mode to the second control mode based on an amount of change in the target pressure and the pressure information.

5. The butterfly valve control device of claim 4, wherein the valve control unit:
determines whether the target pressure is the same as the pressure information,
determines the amount of change in the pressure information when the target pressure is not the same as the pressure information,
maintains the first control mode when the amount of change in the pressure information exceeds a preset reference value, and
switches to the second control mode when the amount of change in the pressure information is less than the preset reference value.

6. The butterfly valve control device of claim 1, wherein:
the valve control unit configures actual measurement information by mapping the pressure information to a current rotation angle of the plate, and
updates the high-speed rotation information for each pressure based on the actual measurement information.

7. The butterfly valve control device of claim 6, wherein the memory is a non-volatile memory.

8. The butterfly valve control device of claim 1, wherein the valve drive unit comprises:
a motor that generates a rotational force for rotating the shaft according to one of the first control signal and the second control signal;
a coupler connected to the shaft and transferring the rotational force provided by the motor;
a gear box provided between the coupler and the motor to adjust a reduction ratio of the rotational force; and
an encoder that generates first rotation angle information according to driving of the motor, and the rotation angle information is generated based on the first rotation angle information.

9. The butterfly valve control device of claim 8, further comprising a second sensing unit that generates a plate image by imaging a plate, wherein the second sensing unit is configured to analyze the plate image and determine a degree of accumulation of by-products in the plate.

10. A method of controlling a butterfly valve, comprising:
providing a butterfly valve, the butterfly valve being placed on a conduit line through which fluid communicates with an inside of a chamber and comprising a valve body in which a valve passage communicating with the conduit line is defined through an inner wall and comprising a plate that is connected to the valve body through a shaft and adjusts a flow rate of fluid passing through the valve passage according to rotation of the shaft in an axial direction;
recalling a rotation angle of the plate corresponding to a set target pressure from high-speed rotation information for each pressure stored in a memory, and performing a first control mode for rotating the plate by controlling the shaft according to the recalled rotation angle of the plate;
determining whether to maintain the first control mode by comparing a pressure of a chamber with the set target pressure, and switching to the second control mode when a difference between the set target pressure and the pressure of the chamber is less than a preset reference value;
calculating a control input for adjusting the rotation angle of the plate such that the pressure of the chamber follows the target pressure, and performing the second control mode for rotating the plate by controlling the shaft based on the control input; and
configuring actual measurement information by mapping the pressure of the chamber to the rotation angle of the plate, and updating the high-speed rotation information for each pressure based on the actual measurement information.
